(19) United States
(12) Patent Application Publication
(10) Pub. No.: US 2008/0032040 A1
(43) Pub. Date: Feb. 7, 2008

(54) Wafer Support and Semiconductor Substrate Processing Method

(76) Inventors: Akira Okabe, Nagasaki (JP); Kazuhisa Kawamoto, Nagasaki (JP)

Correspondence Address: JORDAN AND HAMBURG LLP, 122 EAST 42ND STREET, SUITE 4000, NEW YORK, NY, 10168, US

(21) Appl. No.: 10/594,541

(22) PCT Filed: Nov. 9, 2004
(86) PCT No.: PCT/JP04/16567

§ 371 Date: Oct. 16, 2006

(30) Foreign Application Priority Data
Mar. 29, 2004 (JP) 2004-094230

(51) Int. Cl. C23C 16/455; H01L 21/31

(52) U.S. Cl. 427/96.8; 427/255.27; 438/765; 257/E21.249

(57) ABSTRACT

To provide a wafer support and a semiconductor substrate processing method by which dopants released from a rear surface of a semiconductor substrate can be adequately restrained from reaching a top surface of a semiconductor substrate and a reaction gas can be restrained from reaching a rear surface of the semiconductor substrate. A silicon semiconductor wafer 7 is set on a wafer supporting portion 2 of a wafer support 1, a space is formed between the silicon semiconductor wafer 7 and the counterbored portion 2a, a hydrogen gas 5 flows through a gas supplying path 6, provided in a wafer support rotating member 6a positioned at a central region of the wafer support 1, and flows, via gas supplying penetrating hole portions 3 formed in the central region of the counterbored portion 2a, along a surface of the silicon semiconductor wafer 7 in the space between the semiconductor wafer 7 and the counterbored portion 2a, and hydrogen gas 5 is then discharged from the wafer support 1 upon flowing through the gas discharging penetrating hole portions 4 that are inclined with respect to a vertical direction and put the counterbored portion 2a in communication with an outer surface of the wafer support 1 at the side opposite the side on which the semiconductor wafer 7 is set.

### TECHNICAL FIELD

The present invention relates to a wafer support and a semiconductor substrate processing method. Specifically, the present invention relates to a wafer support and a semiconductor substrate processing method such that, with the wafer support, a space, through which a predetermined gas flows, is formed between a semiconductor substrate setting surface and a semiconductor substrate, and the entry of a reaction gas into this space is restrained.

### BACKGROUND ART

Substrates, having a perfect crystal surface portion without microscopic defects and are obtained by depositing and growing an epitaxial layer on a semiconductor substrate, are widely used in MPUs and memory ICs in recent years. For example, as a method for depositing and growing a silicon epitaxial layer, there is the CVD (chemical vapor deposition) method, with which a reaction gas, containing SiCl₄ or other raw material gas and hydrogen or other reference gas, is supplied to a silicon substrate that is heated to a high temperature to deposit and grow a silicon monocrystal on the silicon substrate.

There are various equipments for depositing and growing an epitaxial layer, and FIG. 1 is a schematic sectional view of an example of a conventional semiconductor manufacturing equipment, with which an epitaxial layer is deposited and grown.

The semiconductor manufacturing equipment shown here has a reaction chamber 101, halogen lamps 106, disposed in the surroundings of the reaction chamber 101, and a wafer support 102 that supports a semiconductor wafer inside the reaction chamber 101. The reaction chamber 101 has a first clamp 109, formed of stainless steel and having a reaction gas inlet 104 formed therein, a second clamp 110, formed of stainless steel and having a reaction gas outlet 105 formed therein, and quartz glass plates 107, the respective ends of which are clamped and fixed by the first clamp and the second clamp.

To deposit and grow an epitaxial layer using the semiconductor manufacturing equipment arranged as described above, a semiconductor wafer 103 is set on the wafer support, a reaction gas is made to flow inside reaction chamber 101 by introducing the reaction gas 108 from the reaction gas inlet 104 and discharging the reaction gas 108 from the reaction gas outlet 105, and the semiconductor wafer 103 is heated by illumination by halogen lamps 106. The epitaxial layer is deposited and grown by the reaction gas and the heat.

In the process of depositing and growing the epitaxial layer, so-called autodoping, that is, a phenomenon, with which, due to heating the semiconductor substrate at a high temperature, dopants in the semiconductor substrate becomes released into the gas phase and the released dopants are taken into the epitaxial layer, occurs. This gives rise to scattering of the dopant concentration distribution in the formed epitaxial layer and the specific resistance distribution inside the epitaxial layer becomes non-uniform.

Here, “dopant” refers to an impurity, which is made up of an element besides the element making up the semiconductor crystal and is added to control the properties of the semiconductor, and for a Group III-V compound semiconductor, such as GaN or GaAs, the Group II elements, Be, Mg, Zn, and Cd, are p type dopants, and the Group VI elements Se and Te and the Group IV element Si are n type dopants.

With inventions disclosed in Japanese Published Unexamined Patent Application No. Hei 10-223545 and Japanese Published Unexamined Patent Application No. 2002-198318, a wafer support is used with which a gas flow is formed from an upper surface to a lower surface of the wafer support to prevent dopants, released from a rear surface (at a side opposite a surface on which an epitaxial layer is formed) of a semiconductor substrate, from reaching a top surface (surface on which the epitaxial layer is formed) of the semiconductor substrate. FIG. 2 is a schematic sectional view of a conventional wafer support, with which a gas flow is formed.

With a wafer support 111 shown in FIG. 2, penetrating hole portions 113 are provided at outermost peripheral portions inside a wafer pocket 112 for setting a semiconductor wafer 114, a raw material gas 116 is supplied to a top surface side of the semiconductor wafer 114, and by heating, an epitaxial layer 115 is grown on the top surface of the semiconductor wafer 114. Here, by the positioning of penetrating hole portions 113, localized gas flows are formed from the top surface of the semiconductor wafer 114, and dopants, released from a rear surface of the semiconductor wafer 114, are discharged without reaching the top surface of the semiconductor wafer 114.

With an invention described in Japanese Published Unexamined Patent Application No. 2003-273037, a rear surface of a semiconductor substrate is exposed to a displacement gas, containing no more than 5 volume % of hydrogen, and the diffusion of dopants, which is reinforced by hydrogen, is prevented across a wide range.

Furthermore, with inventions described in Japanese Published Unexamined Patent Application No. 2003-197532, Japanese Published Unexamined Patent Application No. 2003-197533, and Japanese Published Unexamined Patent Application No. 2003-229370, dopants, released from a semiconductor substrate, are discharged by a gas that is made to flow into a reaction chamber via a hole portion formed in a wafer support to thereby restrain the dopants from reaching a top surface of the semiconductor substrate.

### DISCLOSURE OF THE INVENTION

### Problems to be Solved by the Invention

However, with the method for forming a gas flow from the upper surface to the lower surface of the wafer support as in the inventions described in Japanese Published Unexamined Patent Application No. Hei 10-223545 and Japanese Published Unexamined Patent Application No. 2002-198318, the raw material gas that flows along the upper surface of the wafer support enters into a space between the rear surface of the semiconductor substrate and the wafer support and may cause unwanted epitaxial deposition and growth, etc., on the rear surface of the semiconductor substrate.

With the method for exposing the rear surface of the semiconductor substrate to a gas of low hydrogen content as in the invention described in Japanese Published Unexamined Patent Application No. 2003-273037, the gas of low hydrogen content may flow along the top surface of the semiconductor substrate and may not be able to adequately restrain the dopants from reaching the top surface of the semiconductor substrate.

Furthermore, with the method for discharging the dopant, released from the semiconductor substrate, by the gas that is made to flow through the reaction chamber via a hole portion formed in the wafer support as in the inventions described in Japanese Published Unexamined Patent Application No. 2003-197532, Japanese Published Unexamined Patent Application No. 2003-197533, and Japanese Published Unexamined Patent Application No. 2003-229370, it may not be possible to adequately restrain the dopants from reaching the top surface of the semiconductor substrate.

The present invention has been made in view of the above points and an object thereof is to provide a wafer support and a semiconductor substrate processing method by which dopants released from a rear surface of a semiconductor substrate can be adequately restrained from reaching a top surface of a semiconductor substrate and a reaction gas can be restrained from reaching a rear surface of the semiconductor substrate.

### SUMMARY OF THE INVENTION

To achieve the above object, the present invention provides in a wafer support that supports a semiconductor substrate in a reaction chamber, into which a reaction gas is supplied, a wafer support arranged so that a predetermined gas flows into a predetermined space that is formed between a setting surface for the above-described semiconductor substrate and the above-described semiconductor substrate and is connected to an outer surface other than the above-described semiconductor substrate setting surface.

Here, by a space, which is connected to the outer surface of the wafer support other than the surface at the side on which the semiconductor substrate is set and in which the predetermined gas flows, being formed between the wafer support and the semiconductor substrate that is set thereon, dopants that are released into a gas phase from the semiconductor substrate, gaseous contaminants that are released into the gas phase from the semiconductor substrate, and minute contaminants attached to the wafer support can be effectively discharged along with the predetermined gas via the outer surface of the wafer support other than the surface at the side on which the semiconductor substrate is set, and by the flowing of the predetermined gas, the reaction gas that flows along outer sides of the wafer support can be restrained from entering into the space formed between the semiconductor substrate setting surface and the semiconductor substrate.

Also, by the space of the wafer support, through which the predetermined gas flows, being connected to the outer surface of the wafer support other than the semiconductor substrate setting surface, the dopants released from a rear surface of a semiconductor substrate can be restrained more efficiently from reaching the top surface of the semiconductor substrate than in the case of simply exposing the rear surface of the set semiconductor substrate to the gas. Here, “predetermined gas” refers to a gas that does not react with the semiconductor substrate even upon coming into contact with the semiconductor substrate and has no inadvertent effects on the semiconductor substrate (for example, in the case of an epitaxial equipment, a gas that does not deposit an epitaxial layer onto the semiconductor substrate).

The present invention also provides, in a semiconductor substrate processing method for setting a semiconductor substrate on a wafer support disposed inside a reaction chamber and supplying a reaction gas into the above-described reaction chamber to form a thin film on the above-described semiconductor substrate, a semiconductor substrate processing method, in which the thin film is formed on the above-described semiconductor substrate while making a predetermined gas flow into a predetermined space that is formed between a setting surface for the above-described semiconductor substrate of the above-described wafer support and the above-described semiconductor substrate and is connected to an outer surface other than the above-described semiconductor substrate setting surface.

Here, by supplying the predetermined gas into the space of the wafer support, do pants that are released into a gas phase from the semiconductor substrate, gaseous contaminants that are released into the gas phase from the semiconductor substrate, and minute contaminants attached to the wafer support can be effectively discharged along with the predetermined gas to the outer surface of the wafer support other than the semiconductor substrate setting surface, and by the flowing of the predetermined gas, the reaction gas that flows along outer sides of the wafer support can be restrained from entering into the space formed between the semiconductor substrate setting surface and the semiconductor substrate.

Also, by the space, into which the predetermined gas is supplied, being connected to the outer surface of the wafer support other than the semiconductor substrate setting surface, the dopants released from a rear surface of a semiconductor substrate can be restrained more efficiently from reaching the top surface of the semiconductor substrate than in the case of simply supplying the gas to the rear surface of the set semiconductor substrate.

### EFFECTS OF THE INVENTION

With the wafer support according to the present invention, the dopants released from a rear surface of a semiconductor substrate can be adequately restrained from reaching the top surface of the semiconductor substrate and also, the reaction gas can be restrained from reaching the rear surface of the semiconductor substrate.

With the semiconductor substrate processing method according to the present invention, the dopants released from a rear surface of a semiconductor substrate can be adequately restrained from reaching the top surface of the semiconductor substrate and also, the reaction gas can be restrained from reaching the rear surface of the semiconductor substrate.

### BRIEF DESCRIPTION OF THE DRAWINGS

FIG. 1 is a schematic sectional view of an example of a conventional semiconductor manufacturing equipment, with which an epitaxial layer is deposited and grown;

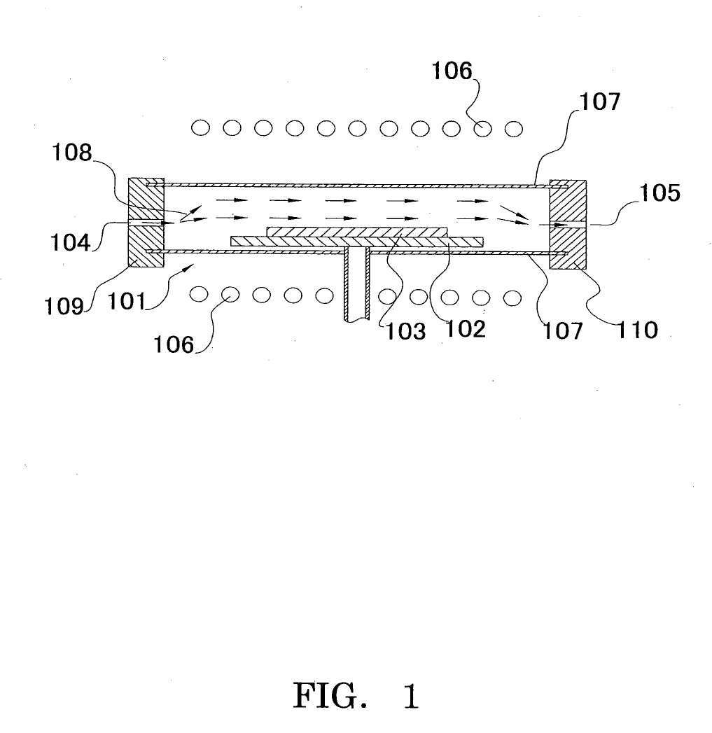

FIG. 2 is a schematic sectional view of a conventional wafer support, with which a gas flow is formed;

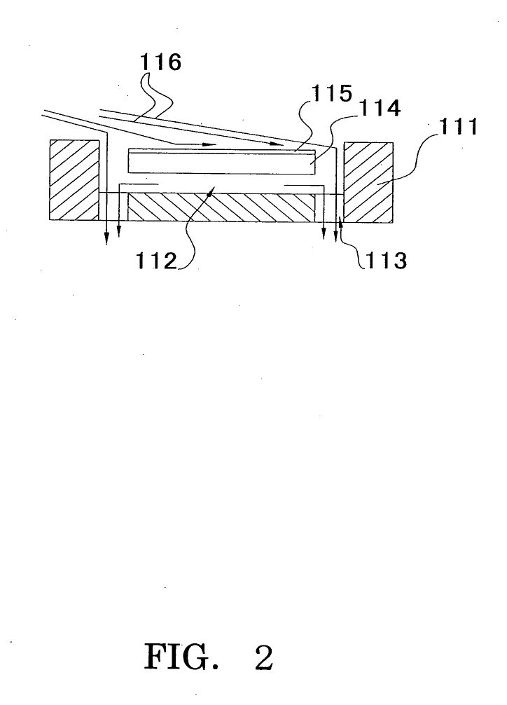

FIG. 3 is a schematic plan view of an example of a wafer type wafer support used in a semiconductor manufacturing equipment to which the present invention is applied;

FIG. 4 is a schematic sectional view of an example of a semiconductor manufacturing equipment equipped with the wafer support, shown in FIG. 3, with a semiconductor wafer supported thereon, and the section of the wafer support is that taken along line I-I of FIG. 3;

FIG. 5 is a schematic plan view of a plural wafer type wafer support used in a semiconductor manufacturing equipment to which the present invention is applied; and

FIG. 6 is a schematic sectional view taken along line II-II of an example in which semiconductor wafers are set on the wafer support shown in FIG. 5.

### DESCRIPTION OF THE SYMBOLS

1 Wafer support
2 Wafer supporting portion
2a Counterbored portion
3 Gas supplying penetrating hole portion
4 Gas discharging penetrating hole portion
5 Hydrogen gas
6 Gas supplying path
6a Wafer support rotating member
7 Silicon semiconductor wafer
8 Reaction chamber
9 Reaction gas inlet
10 Reaction gas outlet
11 Halogen lamp
12 Quartz glass plate
13 Reaction gas containing SiCl₄ gas and hydrogen gas
14 First clamp
15 Second clamp

### BEST MODE FOR CARRYING OUT THE INVENTION

Embodiments of the present invention shall now be described with reference to the drawings to further the understanding of the present invention.

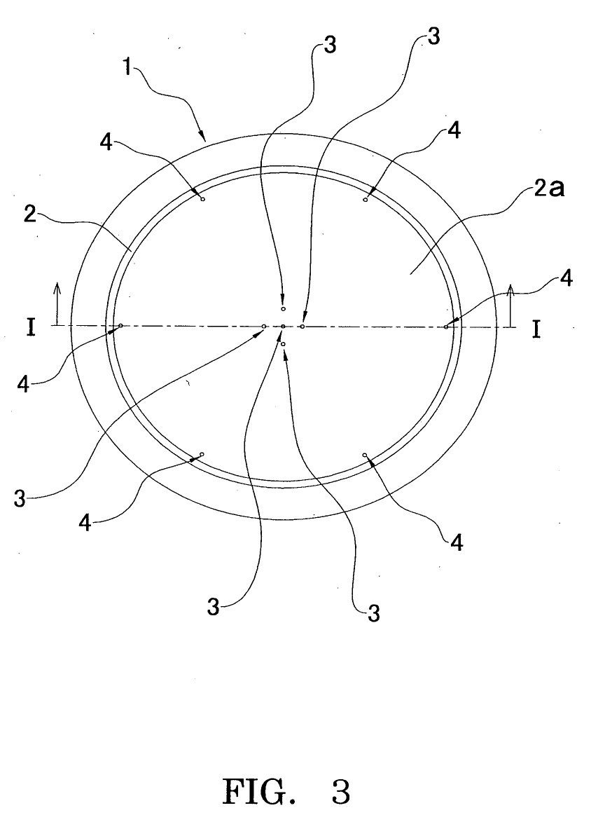

FIG. 3 is a schematic plan view of an example of a wafer type wafer support used in a semiconductor manufacturing equipment to which the present invention is applied. A circular wafer support 1 is depressed in two stages at a central portion and is made up of a wafer supporting portion 2, which is the upper stage and supports a semiconductor substrate, and a lower-stage counterbored portion 2a, provided with five gas supplying penetrating hole portions 3, which are positioned at a central region of the wafer support 1 and through which a predetermined gas is supplied, and six gas discharging penetrating hole portions 4, through which the predetermined gas is discharged.

Here, as long as the wafer support is arranged so that the predetermined gas flows into a predetermined space, formed between a semiconductor wafer setting surface and the semiconductor wafer and connected to an outer surface other than the semiconductor wafer setting surface, the central portion of the wafer support 1 may be depressed in three stages. Setting of the semiconductor wafer in such a depression can prevent the semiconductor wafer from drifting due to a reaction gas flow.

Here, though as long as the wafer support is arranged so that the predetermined gas flows into the predetermined space, formed between the semiconductor wafer setting surface and the semiconductor wafer and connected to the outer surface other than the semiconductor wafer setting surface, any number of gas supplying penetrating hole portions 3 and gas discharging penetrating hole portions 4 may be provided at any position and, for example, may be provided at a surface that connects the wafer supporting portion 2 and the counterbored portion 2a, the gas discharging penetrating hole portions 4 are preferably provided inside a wafer support region that does not exceed the diameter of the semiconductor wafer because the dopants released from a rear surface of a semiconductor substrate can then be efficiently restrained from reaching a top surface of the semiconductor wafer from a rear surface (surface facing the counterbored portion 2a) of the semiconductor wafer.

Also, as long as the wafer support is arranged so that the predetermined gas flows into the predetermined space, formed between the semiconductor wafer setting surface and the semiconductor wafer and connected to the outer surface other than the semiconductor wafer setting surface, gas supplying penetrating hole portions 3 and gas discharging penetrating hole portions 4 may be of any size and, for example, each may be 1 to 10 mm in diameter.

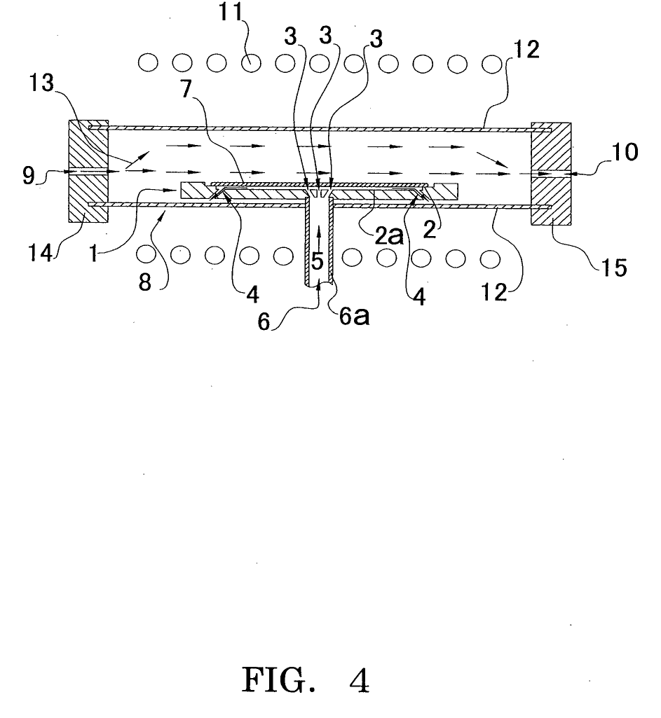

FIG. 4 is a schematic sectional view of an example of a semiconductor manufacturing equipment equipped with the wafer support, shown in FIG. 3, with a semiconductor wafer supported thereon, and the section of the wafer support is that taken along line I-I of FIG. 3.

The semiconductor manufacturing equipment shown in FIG. 4 includes a reaction chamber 8, halogen lamps 11, disposed in the surroundings of the reaction chamber, and a disk-like wafer support 1 that supports the silicon semiconductor wafer 7 inside the reaction chamber. The reaction chamber 8 has a first clamp 14, formed of stainless steel and having a reaction gas inlet 9 formed therein, a second clamp 5, formed of stainless steel and having a reaction gas outlet 10 formed therein, and quartz glass plates 12, the respective ends of which are clamped and fixed by the first clamp and the second clamp. Here, the first clamp 14 and the second clamp 15 may be made of quartz as long as they can clamp and fix the quartz glass plates 12.

The silicon semiconductor wafer 7 is set on the wafer supporting portion 2 of the wafer support 1, a space is formed between the silicon semiconductor wafer 7 and the counterbored portion 2a, a hydrogen gas 5 flows through a gas supplying path 6, provided in a wafer support rotating member 6a positioned at a central region of the wafer support 1, hydrogen gas 5 then flows along a surface of silicon semiconductor wafer 7 upon entering the space between the semiconductor wafer 7 and the counterbored portion 2a via the gas supplying penetrating hole portions 3, formed in the central region of the counterbored portion 2a, and the hydrogen gas 5 is then discharged from the wafer support 1 upon flowing through gas discharging penetrating hole portions 4 that are inclined with respect to a vertical direction and put counterbored portion 2a in communication with an outer surface of the wafer support 1 at the side opposite the side on which the semiconductor wafer 7 is set. The flow rate, pressure, etc., of the hydrogen gas 5 is adjusted so that it flows uniformly along the entirety of the rear surface of the silicon semiconductor wafer 7 and so that the silicon semiconductor wafer 7 is not floated by the hydrogen gas 5. The wafer support rotating member 6a is connected to a driving mechanism (not shown) and the wafer support 1 is thereby enabled to rotate. The discharged hydrogen gas is discharged, along with a reaction gas, from the reaction chamber 8 via the reaction gas outlet 10.

By the hydrogen gas 5 being discharged from the wafer support 1, dopants and gaseous contaminants that are released from the rear surface (surface facing the counterbored portion 2a) of the silicon semiconductor wafer 7 and minute contaminants attached to the wafer support 1 are discharged from the wafer support 1 along with the hydrogen gas 5, thus enabling the dopants to be restrained from reaching the top surface of the silicon semiconductor wafer 7, the uniformity of the dopant concentration distribution in the epitaxial layer that is deposited onto the top surface of the silicon semiconductor wafer 7 to be improved to realize a satisfactory specific resistance distribution, and the rear surface of the silicon semiconductor wafer 7 to be maintained in a clean state and thereby restrain abnormal reactions in the epitaxial growth process.

Also, because by the hydrogen gas 5 flowing between the silicon semiconductor substrate 7 and the counterbored portion 2a, the reaction gas that flows at the outer sides of the wafer support 1 can be restrained from entering into the space formed between the set silicon semiconductor wafer 7 and counterbored portion 2a and unwanted epitaxial deposition and growth and etching reactions at the rear surface of the silicon semiconductor wafer 7 can thereby be restrained, the flatness of the silicon semiconductor wafer 7 can be improved and the occurrence of localized discoloration at the rear surface of the silicon semiconductor wafer 7 can be restrained.

Furthermore, because the hydrogen gas 5 is actively made to flow between the silicon semiconductor wafer 7 and the counterbored portion 2a, the flow rate of the hydrogen gas can be controlled actively, and by supplying the hydrogen gas 5 uniformly between the silicon semiconductor wafer 7 and the counterbored portion 2a, the surface temperature distribution of the wafer support can be made uniform and favorable heat transfer can be realized between the wafer support and the wafer to make the surface temperature distribution of the wafer uniform.

Here, as long as the predetermined gas can be supplied into the space between the silicon semiconductor wafer 7 and the counterbored portion 2a, the gas supplying penetrating hole potions 3 and the gas supplying path 6 do not have to be disposed at the central region of the wafer support 1 and, for example, at least one of the gas discharging penetrating hole portions 4 may be used as the gas supplying penetrating hole portion 3 and the gas supplying path 6 may be connected thereto to supply the predetermined gas.

Also, though an example of supplying hydrogen gas into the gas supplying path 6 is described with the present embodiment, any gas may be used as long as it is a predetermined gas, and an inert gas, such as a gas selected from among nitrogen, helium, neon, argon, krypton, xenon, and radon, may be used or a mixed gas of at least two or more types of these gases may be used.

To perform epitaxial deposition and growth using the above-described semiconductor manufacturing equipment, the silicon semiconductor wafer 7 is set on the disk-like wafer support 1 inside the reaction chamber 8, and a reaction gas 13, containing the silicon tetrachloride (SiCl₄) and hydrogen gas, is introduced into the reaction chamber 8 from the reaction gas inlet 9. The reaction gas 13, which contains SiCl₄ gas and hydrogen gas, flows near the silicon semiconductor wafer 7, light is illuminated into the reaction chamber from the halogen lamps 11 that are disposed in the surroundings of the reaction chamber, the silicon semiconductor wafer 7 is thereby heated, and epitaxial deposition and growth are carried out by the heat and the reaction gas.

Though halogen lamps are used as the light source here, the light source may be any light source as long as it can heat the silicon semiconductor wafer 7 and, for example, infrared lamps may be used instead.

Also, though an example of a semiconductor manufacturing equipment having a reaction chamber with a box-like shape is shown in FIG. 4, the semiconductor manufacturing equipment to which the present invention is applied may have a reaction chamber of any shape as long as the above-described wafer support can be housed and the semiconductor wafer can be heated and, for example, a semispherical dome type reaction chamber or a bell-shaped reaction chamber may be used.

Also, though an example using a silicon substrate was described with the present embodiment, the substrate may be any substrate on which epitaxial growth can be performed and, for example, a gallium arsenide (GaAs) substrate or a zinc telluride (ZnTe) substrate may be used. Also, as long as an epitaxial layer can be deposited and grown in the substrate, any raw material gas may be used and, for example, a gas containing Ga is used when a gallium arsenide substrate is used, and a gas containing Te is used when a zinc telluride substrate is used.

An epitaxial growth process shall now be described.

While the wafer support 1, supporting the silicon semiconductor wafer 7, is rotated by means of the driving mechanism (not shown), the silicon semiconductor wafer 7 is heated to 1000 to 1200° C. by halogen lamps 11.

Next, the reaction gas 13, containing SiCl₄ gas and hydrogen gas, is then introduced into the reaction chamber 8 from the reaction gas inlet 9 to carry out epitaxial growth.

Though SiCl₄ gas is introduced into the reaction chamber 8 as the raw material gas in the reaction gas, any gas containing silicon atoms may be used and, for example, silane trichloride (SiHCl₃) gas, silane dichloride (SiH₂Cl₂) gas, or silane (SiH₄) gas may be introduced into the reaction chamber 8.

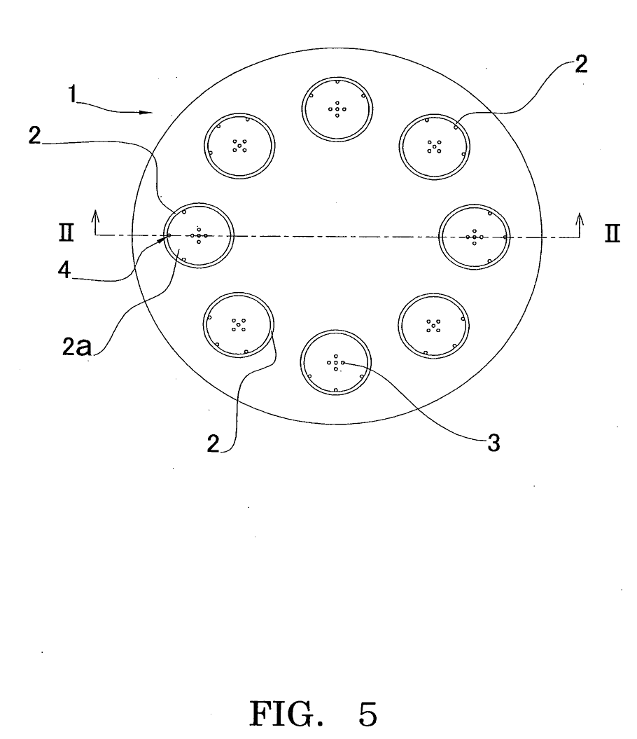

FIG. 5 is a schematic plan view of a plural wafer type wafer support used in a semiconductor manufacturing equipment to which the present invention is applied. On a circular wafer support 1, semiconductor wafer setting portions, each being circularly depressed in two stages, are positioned along an annulus, and epitaxial layers can be deposited and grown on a plurality of semiconductor wafers simultaneously.

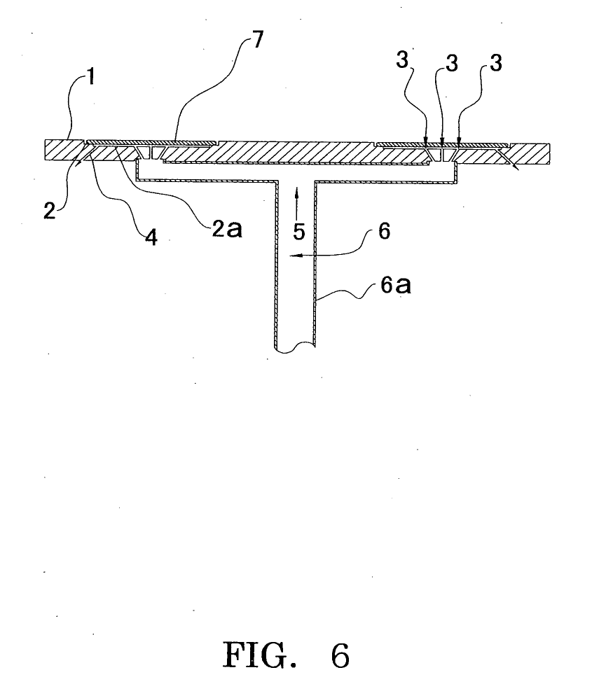

FIG. 6 is a schematic sectional view taken along line II-II of an example in which semiconductor wafers are set on the wafer support shown in FIG. 5.

A silicon semiconductor wafer 7 is set on each wafer supporting portion 2 of the wafer support 1, a space is formed between the silicon semiconductor wafer 7 and a counterbored portion 2a, a hydrogen gas 5 flows through a gas supplying path 6 positioned at a central region of the wafer support 1, the hydrogen gas 5 then flows along a surface of the silicon semiconductor wafer 7 upon entering the space between the semiconductor wafer 7 and the counterbored portion 2a via the gas supplying penetrating hole portions 3, formed in a central region of the counterbored portion 2a, and the hydrogen gas 5 is then discharged from the wafer support 1 upon flowing through gas discharging penetrating hole portions 4 that put counterbored portion 2a in communication with an outer surface of the wafer support 1 at the side opposite the side on which the semiconductor wafer 7 is set. Because the gas supplying path 6 extends from the central region of the wafer support 1 toward the outer peripheral portions of the wafer support 1, the gas discharging penetrating hole portions 4 are provided only at the outer peripheral portion sides of the wafer support 1.

What is claimed is:

1. A wafer support that supports a semiconductor substrate in a reaction chamber, into which a reaction gas is supplied,
the wafer support being arranged so that a predetermined gas flows into a predetermined space that is formed between a semiconductor substrate setting surface and the semiconductor substrate and is connected to an outer surface other than the semiconductor substrate setting surface.

2. The wafer support according to claim 1, wherein
a supply source of the predetermined gas is formed at a substantially central region of the wafer support.

3. The wafer support according to claim 1 or 2, wherein
the predetermined gas is hydrogen gas.

4. The wafer support according to claim 1 or 2, wherein
the predetermined gas is an inert gas.

5. A semiconductor substrate processing method for setting a semiconductor substrate on a wafer support disposed inside a reaction chamber and supplying a reaction gas into the reaction chamber to form a thin film on the semiconductor substrate, the semiconductor substrate processing method being characterized in that the thin film is formed on the semiconductor substrate while making a predetermined gas flow into a predetermined space that is formed between a semiconductor substrate setting surface of the wafer support and the semiconductor substrate and is connected to an outer surface other than the semiconductor substrate setting surface.

6. The semiconductor substrate processing method according to claim 5,
wherein the predetermined gas is supplied from a substantially central region of the wafer support.

7. The semiconductor substrate processing method according to claim 5 or 6,
the predetermined gas is hydrogen gas.

8. The semiconductor substrate processing method according to claim 5 or 6,
the predetermined gas is an inert gas.
